(19) United States
(12) Patent Application Publication
(10) Pub. No.: US 2013/0170154 A1
(43) Pub. Date: Jul. 4, 2013

(54) PRINTED CIRCUIT BOARD HAVING EMBEDDED CAPACITOR AND METHOD OF MANUFACTURING THE SAME

(71) Applicant: SAMSUNG ELECTRO-MECHANICS CO., LTD., Gyeonggi-do (KR)

(72) Inventors: Doo Hwan LEE, Gyeonggi-do (KR); Jong In RYU, Chungcheongnam-do (KR); Jin Won LEE, Gyeonggi-do (KR); Moon Il KIM, Gyeonggi-do (KR)

(73) Assignee: SAMSUNG ELECTRO-MECHANICS CO., LTD., Gyeonggi-do (KR)

(21) Appl. No.: 13/734,546

(22) Filed: Jan. 4, 2013

(30) Foreign Application Priority Data
Jan. 4, 2012 (KR) 10-2012-0001125

(51) Int. Cl. H05K 3/32; H05K 1/16

(52) U.S. Cl. CPC H05K 3/32; H05K 1/162
USPC 361/748; 29/832

(57) ABSTRACT

Provided is a printed circuit board having an embedded capacitor including at least one sheet-shaped capacitor, an insulating material configured to cover the sheet-shaped capacitor, and a capacitor device mounted in the insulating material to be parallelly disposed at one side of the sheet-shaped capacitor, improving reliability of the substrate.

### CROSS-REFERENCE TO RELATED APPLICATIONS

This application claims the benefit of Korean Patent Application No. 10-2012-0001125 filed with the Korea Intellectual Property Office on Jan. 4, 2012, the disclosure of which is incorporated herein by reference.

### BACKGROUND OF THE INVENTION

1. Field of the Invention

The present invention relates to a printed circuit board having an embedded capacitor and method of manufacturing the same.

2. Description of the Related Art

In recent times, with development of electronic industries, requirements for high functionality and compact structures of electronic parts are rapidly increasing, and thus, high density interconnection and a small thickness of printed circuit boards, on which the electronic parts are mounted, are also required.

In order to reflect such requirements, there is provided another component-mounting technique, different from a conventional component-mounting technique, for example, an embedded printed circuit board in which electronic parts such as active devices or passive devices are mounted to implement high integration of parts, improvement in reliability, and improvement in performance of a package itself through organic combinations.

Among them, a passive device-embedded printed circuit board technique refers to a technique of mounting active devices such as resistors or capacitors in the board using novel materials and processes. Here, a board having an embedded capacitor refers to a printed circuit board having an embedded capacitor.

The printed circuit board having an embedded capacitor may be manufactured using a method of inserting a chip capacitor into the board or a method of mounting a sheet-shaped capacitor. While the chip capacitor insertion method has an advantage with no limit in capacitance or temperature characteristics of a device, the chip capacitor cannot be easily mounted due to its thickness and the chip capacitor cannot be easily disposed in the board due to a narrow space.

On the other hand, since the sheet-shaped capacitor mounting method allows that the capacitor can be disposed on a front surface of the board, the method has an advantage of relatively improving stability and efficiency of current supply in comparison with the chip capacitor in which supply of current is limited to an electrode position. However, dielectric capacitance cannot be easily increased due to limitation in material. In addition, since adhesion to a board material and a pattern caused by a board manufacturing process are used in an electrode of the material, it is difficult to control tolerance of the capacitance within a small range.

Therefore, in this field, as the chip capacitor and the sheet-shaped capacitor are mounted in the same layer of the board, it is needed to provide a printed circuit board having an embedded capacitor and a method of manufacturing the same that are capable of overcoming the limitations of the chip capacitor mounting method and the sheet-shaped capacitor mounting method.

### SUMMARY OF THE INVENTION

The present invention has been invented in order to overcome the above-described problems and it is, therefore, an object of the present invention to provide a printed circuit board having an embedded capacitor and a method of manufacturing the same that are capable of compensating limitations of the chip capacitor mounting method and the sheet-shaped capacitor mounting method to effectively improve performance thereof by mounting a sheet-shaped capacitor and a chip capacitor in the same layer of the board.

In accordance with one aspect of the present invention to achieve the object, there is provided a printed circuit board having an embedded capacitor including: at least one sheet-shaped capacitor; an insulating material configured to cover the sheet-shaped capacitor; and a chip capacitor mounted in the insulating material to be parallelly disposed at one side of the sheet-shaped capacitor.

The chip capacitor may be parallelly disposed at one side of the sheet-shaped capacitor in a horizontal direction.

The chip capacitor may be connected to the sheet-shaped capacitor in series or in parallel.

The sheet-shaped capacitor may include a dielectric body; and first and second pattern electrodes formed at upper and lower surfaces of the dielectric body, respectively.

The dielectric body may be formed of any one of an organic material, ceramic and a ceramic-filled organic material, or a combination thereof.

The first and second pattern electrodes may be formed of a metal foil.

The printed circuit board having an embedded capacitor may further include a via formed by processing the insulating material to electrically connect the sheet-shaped capacitor and the chip capacitor; and a circuit pattern formed inside or an outermost surface of the insulating material.

The chip capacitor may include a first device electrode; and a second device electrode formed at a position opposite to the first device electrode.

The chip capacitor may be formed such that the first and second device electrodes are exposed to the insulating material, and the first and second device electrodes may be electrically connected to the sheet-shaped capacitor through a circuit pattern disposed at the outermost surface of the insulating material.

The chip capacitor may be formed such that the first and second device electrodes are buried in the insulating material, and the first and second device electrodes may be electrically connected to the sheet-shaped capacitor through the via.

In accordance with another aspect of the present invention to achieve the object, there is provided a method of manufacturing a printed circuit board having an embedded capacitor including: forming at least one sheet-shaped capacitor and an insulating material configured to cover the sheet-shaped capacitor; and mounting a chip capacitor in the insulating material to be parallelly disposed at one side of the sheet-shaped capacitor.

Forming the at least one sheet-shaped capacitor and the insulating material configured to cover the sheet-shaped capacitor may include providing a dielectric body; forming a first pattern electrode on one surface of the dielectric body; forming a first insulating material to cover the first pattern electrode; and forming a second pattern electrode on the other surface of the dielectric body to oppose the first pattern electrode.

Mounting the chip capacitor in the insulating material to be parallelly disposed at one side of the sheet-shaped capacitor may include forming a cavity to pass through an area of the first insulating material in which the first and second pattern electrodes are not formed; mounting the chip capacitor in the cavity; and forming a second insulating material to cover the chip capacitor.

The method may further include, after forming the cavity, attaching a fixing tape to one surface of the first insulating material to cover the cavity; and after forming the second insulating material, removing the fixing tape.

The method may further include, after forming the second insulating material, processing at least one insulating material of the first and second insulating materials and forming a via to electrically connect the sheet-shaped capacitor and the chip capacitor; and forming a circuit pattern on at least one insulating material of the first and second insulating materials.

Forming the insulating material to cover the at least one sheet-shaped capacitor and the sheet-shaped capacitor may include providing a dielectric body; forming a first pattern electrode on one surface of the dielectric body; forming a first insulating material to cover the first pattern electrode; forming a second pattern electrode on the other surface of the dielectric body to oppose the first pattern electrode; and forming a second insulating material to cover the second pattern electrode.

Mounting the chip capacitor in the insulating material to be parallelly disposed at one side of the sheet-shaped capacitor may include forming a cavity to pass through areas of the first and second insulating materials in which the first and second pattern electrodes are not formed; mounting the chip capacitor in the cavity; and forming an outer insulating material to cover the chip capacitor.

The method may further include, after forming the cavity, attaching a fixing tape to one surface of the first or second insulating material to cover the cavity, and after forming the outer insulating material, removing the fixing tape.

The method may further include, before forming the cavity, forming an inner layer via to process at least one insulating material of the first and second insulating materials; and forming an inner layer circuit pattern on at least one insulating material of the first and second insulating materials.

The method may further include, after forming the outer insulating material, forming an outer layer via to process the outer insulating material; and forming an outer layer circuit pattern on the outer insulating material.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a printed circuit board having an embedded capacitor in accordance with an exemplary embodiment of the present invention;

FIG. 2 is a plan view of the printed circuit board having an embedded capacitor in accordance with an exemplary embodiment of the present invention;

FIG. 3 is a cross-sectional view of a printed circuit board having an embedded capacitor in accordance with another exemplary embodiment of the present invention;

FIGS. 4 to 12 are cross-sectional views showing a process of manufacturing a printed circuit board having an embedded capacitor in accordance with an exemplary embodiment of the present invention;

FIG. 4 is a cross-sectional view showing first and second electrode layers formed on upper and lower surfaces of a dielectric body, respectively;

FIG. 5 is a cross-sectional view showing that a first pattern electrode is formed by selectively removing a first electrode layer;

FIG. 6 is a cross-sectional view showing that a first insulating material and a first metal layer are applied to cover the first pattern electrode;

FIG. 7 is a cross-sectional view showing that a second pattern electrode is formed by selectively removing a second electrode layer;

FIG. 8 is a cross-sectional view showing that a cavity is formed to pass through the first insulating material of a region in which the first and second pattern electrodes are not formed;

FIG. 9 is a cross-sectional view showing that a fixing tape is attached to an upper surface of the first insulating material to cover the cavity, and a chip capacitor is mounted in the cavity;

FIG. 10 is a cross-sectional view showing that a second insulating material and a second metal layer are applied to cover the second pattern electrode;

FIG. 11 is a cross-sectional view showing that the fixing tape was removed;

FIG. 12 is a cross-sectional view showing that a via passing through the first and second insulating materials, and first and second circuit patterns are formed;

FIGS. 13 to 23 are cross-sectional views a process of manufacturing a printed circuit board having an embedded capacitor in accordance with another exemplary embodiment of the present invention;

FIG. 13 is a cross-sectional view showing that first and second electrode layers are formed on upper and lower surfaces of a dielectric body, respectively;

FIG. 14 is a cross-sectional view showing that a first pattern electrode is formed by selectively removing the first electrode layer;

FIG. 15 is a cross-sectional view showing that a first insulating material and a first metal layer are applied to cover the first pattern electrode;

FIG. 16 is a cross-sectional view showing that a second pattern electrode is formed by selectively removing the second electrode layer;

FIG. 17 is a cross-sectional view showing that a second insulating material and a second metal layer are applied to cover the second pattern electrode;

FIG. 18 is a cross-sectional view showing that first and second vias and first and second circuit patterns configuring the first and second insulating materials are formed;

FIG. 19 is a cross-sectional view showing that a cavity configuring the first and second insulating materials of a region, in which the first and second pattern electrodes are not formed, is formed;

FIG. 20 is a cross-sectional view showing that a fixing tape is attached to a lower surface of the second insulating material to cover the cavity, and a chip capacitor is mounted in the cavity;

FIG. 21 is a cross-sectional view showing that a third insulating material and a third metal layer covering the first circuit pattern are formed;

FIG. 22 is a cross-sectional view showing that the fixing tape is removed, and a fourth insulating material and a fourth metal layer covering the second circuit pattern are formed;

FIG. 23 is a cross-sectional view showing third and fourth vias and third and fourth circuit patterns configuring the third and fourth insulating materials are formed; and

FIG. 24 is a cross-sectional view showing a variant of the vias showing in FIG. 23.

### DETAILED DESCRIPTION OF THE PREFERABLE EMBODIMENTS

Terms used herein and the following claims should not be construed as limited to conventional or dictionary definition but as meanings and concepts meeting with the technical spirit of the present invention based on the principle that the inventor could appropriately define concepts of the terms to describe the best mode of the invention.

Accordingly, it will be appreciated by those skilled in the art that the detailed description given herein with respect to these figures is for explanatory purposes as the invention extends beyond these limited embodiments, and various equivalents, modifications and variations may be made in these embodiments without departing from the principles and spirit of the general inventive concept.

Hereinafter, embodiments of the present invention will be described in detail with reference to the accompanying drawings.

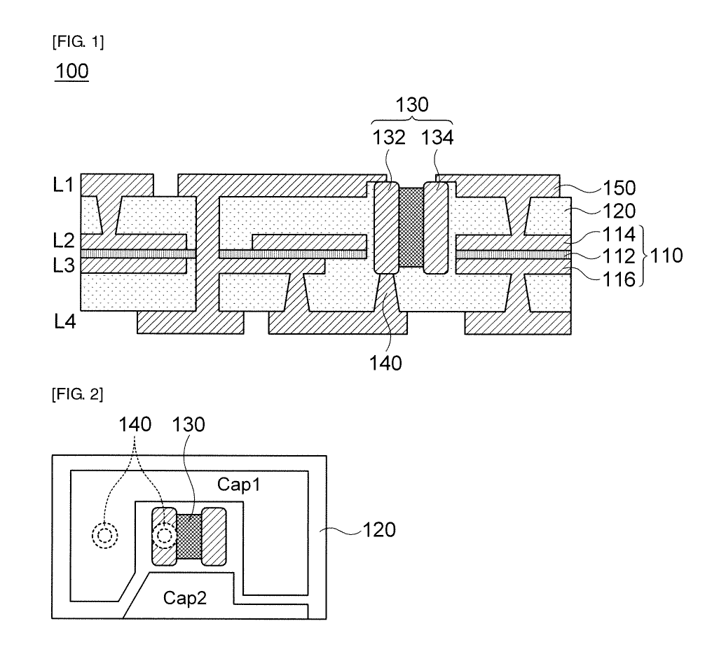

FIG. 1 is a cross-sectional view of a printed circuit board having an embedded capacitor in accordance with an exemplary embodiment of the present invention.

As shown in FIG. 1, a printed circuit board having an embedded capacitor 100 includes at least one sheet-shaped capacitor 110, an insulating material 120 and a chip capacitor 130.

The sheet-shaped capacitor 110, which is a sheet-type capacitor, includes a dielectric body 112, and first and second pattern electrodes 114 and 116.

The dielectric body 112 formed of any one material selected from an organic material, ceramic and a ceramic-containing organic material, or a combination thereof, may have a small thickness to maximize a capacitance.

The first pattern electrode 114 may be formed on an upper surface of the dielectric body 112, and may be formed of a metal foil such as copper (Cu), silver (Ag), gold (Au), aluminum (Al), iron (Fe), titanium (Ti), tin (Sn), nickel (Ni), molybdenum (Mo), or the like.

Here, the metal foil may include a general metal layer, a plated metal layer, or a sputtered metal layer.

The second pattern electrode 116 may be formed on a lower surface of the dielectric body 112 to oppose the first pattern electrode 112, and may be formed of the same material as the first pattern electrode 114.

The insulating material 120, which is a means for covering the sheet-shaped capacitor 110, may be formed of various materials, having small electric conductivity and through which current almost cannot pass, such as prepreg, polyimide, polyethyeleneterepthalate (PET), cyanide ester, Ajinomoto build-up film (ABF), epoxy, or the like.

The chip capacitor 130 includes a first device electrode 132, and a second device electrode 134 formed at a position opposite to the first device electrode 132, and is mounted in the insulating material 120 to be parallelly disposed at one side of the sheet-shaped capacitor 110. In addition, the chip capacitor 130 may be connected to the sheet-shaped capacitor 110 in series or in parallel.

More specifically, the chip capacitor 130 may be implemented in the same layer as the sheet-shaped capacitor 110 to be parallelly disposed at one side of the sheet-shaped capacitor 110 in a horizontal direction. As described above, as the chip capacitor 130 is parallelly disposed in the same layer as the sheet-shaped capacitor 110, the entire thickness of the substrate can be reduced, and the thin substrate in which two kinds of capacitors can be mounted can be manufactured.

In addition, since current flows from chip capacitor 130 to the sheet-shaped capacitor 110, insufficiency of stable supply capacity of the current generated due to limited interconnection in the circuit, to which the chip capacitor 130 is connected, can be supplemented by the sheet-shaped capacitor 110 to improve operational reliability. That is, the current loss generated from the structure in which only the chip capacitor 130 is mounted can be supplemented by the sheet-shaped capacitor 110, and insufficiency of the capacity due to material limitations of the sheet-shaped capacitor 110 can be supplemented by the chip capacitor 130.

Meanwhile, the printed circuit board having an embedded capacitor 100 in accordance with an exemplary embodiment of the present invention may further include a via 140 and a circuit pattern 150.

The via 140 is formed by processing the insulating material 120 to electrically connect the sheet-shaped capacitor 110 and the chip capacitor 130.

The circuit pattern 150, which is a means formed at the outermost surface of the insulating material 120, may be formed using various techniques such as a subtractive technique, an additive technique and a semi-additive technique. The circuit pattern 150 may be formed of a metal material such as copper (Cu), silver (Ag), gold (Au), aluminum (Al), iron (Fe), titanium (Ti), tin (Sn), nickel (Ni) or molybdenum (Mo).

Here, as shown in FIG. 1, when the first and second device electrodes 132 and 134 of the chip capacitor 130 are formed to be exposed to the insulating material 120, the first and second device electrodes 132 and 134 may be electrically connected to the sheet-shaped capacitor 110 through the circuit pattern 150 formed at the outermost surface of the insulating material 120.

More specifically describing, when the first and second device electrodes 132 and 134 are exposed to the insulating material 120 to be adjacent to an upper portion of the insulating material 120, the first and second device electrodes 132 and 134 may be configured to be directly connected to the circuit pattern 150 disposed at the outermost surface of the insulating material 120 to be electrically connected to the sheet-shaped capacitor 110 via the circuit pattern 150.

FIG. 2 is a plan view showing the printed circuit board having an embedded capacitor in accordance with an exemplary embodiment of the present invention, when seen from an upper portion of L3 of FIG. 1.

As shown in FIG. 2, provided that the sheet-shaped capacitor 110 is constituted by Cap1 and Cap2, the chip capacitor 130 may be disposed between Cap1 and Cap2, and may electrically connect the device electrode of the chip capacitor 130 and the sheet-shaped capacitor 110 through the via 140.

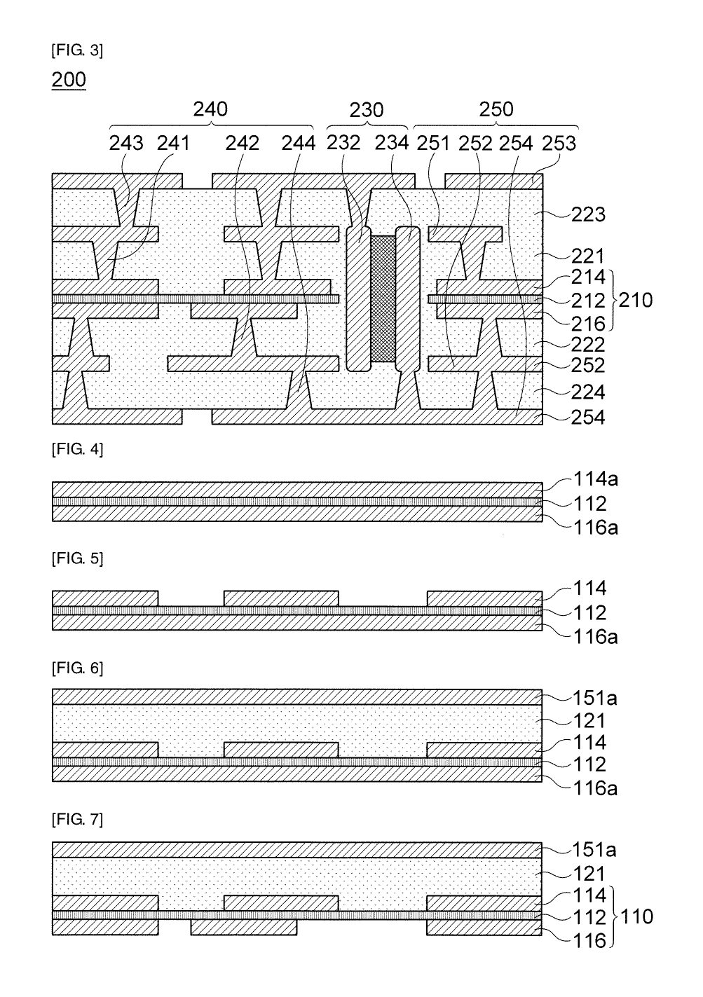

FIG. 3 is a cross-sectional view showing a printed circuit board having an embedded capacitor in accordance with another exemplary embodiment of the present invention.

As shown in FIG. 3, the printed circuit board having an embedded capacitor 200 includes at least one sheet-shaped capacitor 210, an insulating material 220 and a chip capacitor 230.

The sheet-shaped capacitor 210, which is a sheet-type capacitor, includes a dielectric body 212, and first and second pattern electrodes 214 and 216.

The dielectric body 212, which is a means formed of any one of an organic material, ceramic, and a ceramic-filled organic material or a combination thereof, may be formed as a thin structure to maximize a capacitance value.

The first pattern electrode 214 may be formed on an upper surface of the dielectric body 112, and may be formed of a metal foil such as copper (Cu), silver (Ag), gold (Au), aluminum (Al), iron (Fe), titanium (Ti), tin (Sn), nickel (Ni) or molybdenum (Mo).

Here, the metal foil may include a general metal layer, a plated metal layer, or a sputtered metal layer.

The second pattern electrode 216 may be formed at a lower surface of the dielectric body 212 to oppose the [symbol] first pattern electrode 214, and may be formed of the same material as the first pattern electrode 214.

The insulating material 220, which is a means for covering the sheet-shaped capacitor 210, may be formed of various materials having low electrical conductivity and through which little current can pass, such as prepreg, polyimide, polyethyeleneterepthalate (PET), cyanide ester, Ajinomoto build up film (ABF), epoxy, or the like.

The chip capacitor 230 includes a first device electrode 232 and a second device electrode 234 disposed to opposite the first device electrode 232, and mounted in the insulating material 220 to be parallelly disposed at one side of the sheet-shaped capacitor 210. In addition, the chip capacitor 230 may be configured to be connected to the sheet-shaped capacitor 210 in series or in parallel.

More specifically describing, the chip capacitor 230 may be implemented to be parallelly disposed at one side of the sheet-shaped capacitor 210 in a horizontal direction. As described above, as the chip capacitor 230 is implemented to be disposed parallel to the sheet-shaped capacitor 210, the entire thickness of the substrate can be reduced and a thin substrate can be manufactured with two kinds of capacitors simultaneously mounted therein.

In addition, when only the chip capacitor 230 is mounted, an interconnection to an active device disposed thereon or a periphery thereof may be formed in a certain pattern only, and thus, current supply may be unstable in comparison with the case of the sheet-shaped capacitor in which an electrode is disposed at a front surface thereof to be connected in various patterns. Here, instability of the current caused thereby may be supplemented by the sheet-shaped capacitor 210 to improve operational reliability.

Further, in the case of the sheet-shaped capacitor, limitations in capacitance caused by limitations in material can be supplemented by the chip capacitor 230.

Meanwhile, the printed circuit board having an embedded capacitor 200 in accordance with another exemplary embodiment of the present invention may further include a via 240 and a circuit pattern 250.

The via 240 may be constituted by inner layer vias 241 and 242 formed inside the insulating material 220, and outer layer vias 243 and 244 connected to the circuit pattern formed at the outermost surface of the insulating material 220.

The circuit pattern 250, which is a means formed in the insulating material 220 and formed at the outermost surface of the insulating material 220, may be constituted by inner layer circuit patterns 251 and 252 formed inside the insulating material 220 and outer layer circuit patterns 253 and 254 formed at the outermost surfaces of the insulating material 220.

Here, the circuit pattern 250 may be formed using various techniques such as a subtractive technique, an additive technique and a semi-additive technique. The circuit pattern 150 may be formed of a metal material such as copper (Cu), silver (Ag), gold (Au), aluminum (Al), iron (Fe), titanium (Ti), tin (Sn), nickel (Ni) or molybdenum (Mo).

Here, as shown in FIG. 3, when the first and second device electrodes 232 and 234 of the chip capacitor 230 are formed to be buried in the insulating material 220, the first and second device electrodes 232 and 234 may be electrically connected to the sheet-shaped capacitor 210 through the outer layer vias 243 and 244.

More specifically describing, when the first and second device electrodes 232 and 234 are buried in the insulating material 220 to be formed inside the insulating material 220, the first and second device electrodes 232 and 234 may be configured to be directly connected to the outer layer vias 243 and 244 connected to the circuit pattern 150 disposed at the outermost surface of the insulating material 220, thereby being electrically connected to the sheet-shaped capacitor 210 through the outer layer vias 243 and 244.

Hereinafter, a process of manufacturing a printed circuit board in accordance with an exemplary embodiment of the present invention will be described.

FIGS. 4 to 12 are cross-sectional views showing a process of manufacturing a printed circuit board having an embedded capacitor in accordance with an exemplary embodiment of the present invention.

First, as shown in FIG. 4, a dielectric body 112 is provided, and first and second electrode layers 114a and 116a are formed on upper and lower surfaces of the dielectric body 112. Here, the dielectric body 112 may be formed of any one of an organic material, ceramic, and a ceramic-filled organic material or a combination thereof, and may be formed as a thin structure to maximize a capacitance value.

In addition, the first and second electrode layers 114a and 116a may be formed of a metal foil such as copper (Cu), silver (Ag), gold (Au), aluminum (Al), iron (Fe), titanium (Ti), tin (Sn), nickel (Ni) or molybdenum (Mo).

Here, the first and second electrode layers 114a and 116a may be formed on the upper and lower surfaces of the dielectric body 112 through any one method of sputtering, attachment, or plating.

Hereinafter, as shown in FIG. 5, the first electrode layer 114a is selectively removed to form a first pattern electrode 114. Here, the first pattern electrode 114 may be formed using a method of applying a resin or a film type resist on the first electrode layer 114a to form a pattern, opening a portion to be etched through an exposure and development process, and etching the portion using an etching solution or plating the developed portion only. Of course, the first pattern electrode 114 may be formed using the other various methods.

Next, as shown in FIG. 6, a first insulating material 121 and a first metal layer 151a configured to cover the first pattern electrode 114 are formed. Here, first insulating material 121 may be formed of various materials having low electrical conductivity and through which little current can pass, such as prepreg, polyimide, polyethyeleneterepthalate (PET), cyanide ester, Ajinomoto build up film (ABF), epoxy, or the like.

In addition, the first metal layer 151a may be formed of a metal material such as copper (Cu), silver (Ag), gold (Au), aluminum (Al), iron (Fe), titanium (Ti), tin (Sn), nickel (Ni) or molybdenum (Mo).

Next, as shown in FIG. 7, the second electrode layer 116a is selectively removed to form a second pattern electrode 116.

Here, the first and second pattern electrodes 114 and 116 may be implemented through in a method of simultaneously forming and depositing both patterns on a circuit, which is used in a conventional printed circuit board, in addition to a sequential deposition method in which a single surface circuit is formed and deposited and another circuit is formed and deposited on the opposite surface.

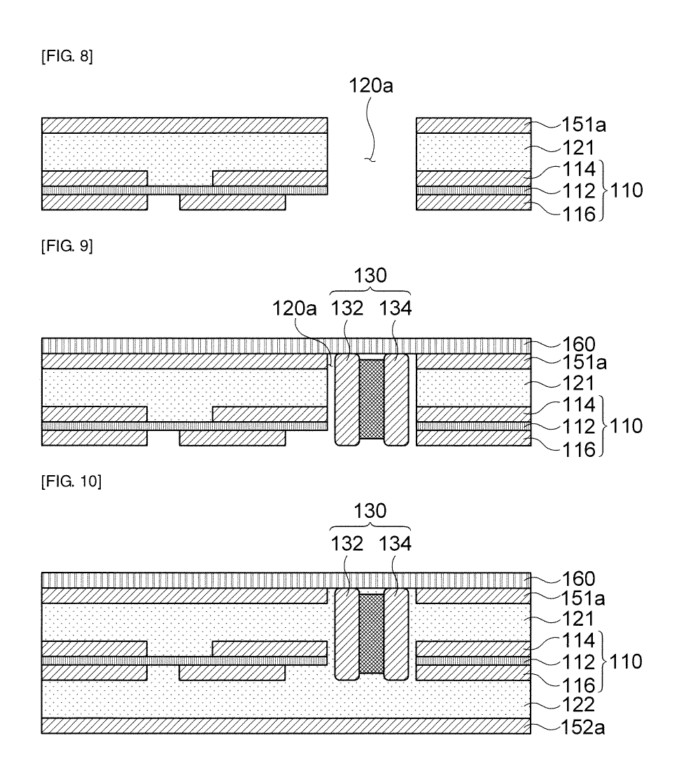

Next, as shown in FIG. 8, a cavity 120a is formed to pass through an area of the first insulating material 121 in which the first and second pattern electrodes 114 and 116 are not formed. That is, in order to mount the chip capacitor 130, the cavity 120a is formed to pass through the region of the insulating material, in which the first and second pattern electrodes 114 and 116 are not formed, from one surface to the other surface.

In addition, the cavity 120a may be formed in the first insulating material 121 through laser cutting, routing, punching, or the like.

Next, as shown in FIG. 9, a fixing tape 160 is attached to an upper surface of the first insulating material 121 to cover the cavity 120a, and the chip capacitor 130 is inserted into the cavity 120a.

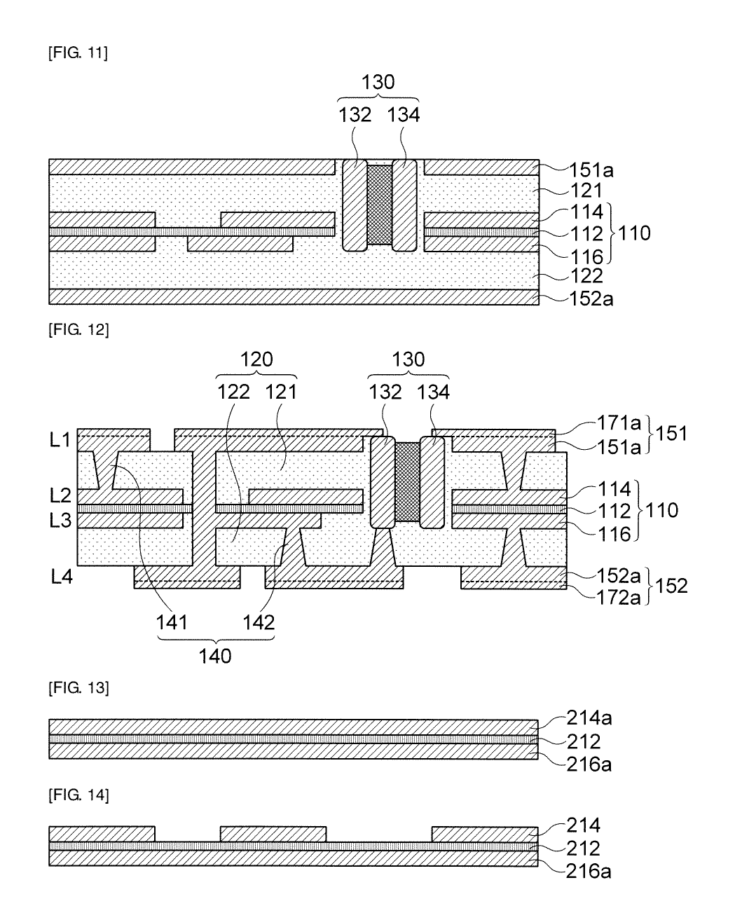

Then, as shown in FIG. 10, a second insulating material 122 and a second metal layer 152a configured to cover the second pattern electrode 116 are sequentially deposited and formed, and as shown in FIG. 11, the fixing tape 160 is removed.

As shown in FIG. 12, a via 140 and a circuit pattern 150 through which the insulating material 120 is processed are formed. More specifically describing, first and second circuit patterns 151 and 152 are formed at the outermost surfaces of the first and second vias 141 and 142 through which the first and second insulating materials 121 and 122 are processed, and the first and second insulating materials 121 and 122.

For this, after forming the first and second via-holes through which the first and second insulating materials 121 and 122 are processed, upper and lower surfaces of the first and second metal layers 151a and 152a including the first and second via-holes are plated to form first and second plated layers 171a and 172a, and the first and second metal layers 151a and 152a plated with the first and second plated layers 171a and 172a are selectively removed to form first and second vias 141 and 142, and first and second circuit patterns 151 and 152. Here, the via-holes may be formed using a computer numerical control (CNC) drill or a laser. Here, an additive technique may be used as the circuit forming technique.

A resist having an opening configured to expose portions of the first and second circuit patterns 151 and 152 is formed in the printed circuit board having an embedded capacitor, a process of forming a surface-treated layer (not shown) on the exposed first and second circuit patterns 151 and 152 may be formed, and an outer layer may be further formed according to a conventional buildup process.

Hereinafter, a process of manufacturing a printed circuit board having an embedded capacitor in accordance with another exemplary embodiment of the present invention will be described.

FIGS. 13 to 23 are cross-sectional views showing the process of manufacturing the printed circuit board having an embedded capacitor in accordance with another exemplary embodiment of the present invention.

First, as shown in FIG. 13, a dielectric body 212 is provided, and first and second electrode layers 214a and 216a are formed on upper and lower surfaces of the dielectric body 212, respectively. Here, the dielectric body 212 may be formed of any one of an organic material, ceramic, and a ceramic-filled organic material or a combination thereof, and may be formed as a thin structure to maximize a capacitance value.

In addition, the first and second electrode layers 214a and 216a may be formed of a metal foil such as copper (Cu), silver (Ag), gold (Au), aluminum (Al), iron (Fe), titanium (Ti), tin (Sn), nickel (Ni) or molybdenum (Mo).

Here, the first and second electrode layers 214a and 216a may be formed on the upper and lower surfaces of the dielectric body 212 using any one method of sputtering, attachment, or plating.

Next, as shown in FIG. 14, the first electrode layer 214a is selectively removed to form a first pattern electrode 214. Here, the first pattern electrode 214 may be formed using a method of applying a resin or a film type resist on the first electrode layer 214a to form a pattern, opening a portion to be etched through an exposure and development process, and etching the portion using an etching solution or plating the developed portion only. Of course, the first pattern electrode 214 may be formed using the other various methods.

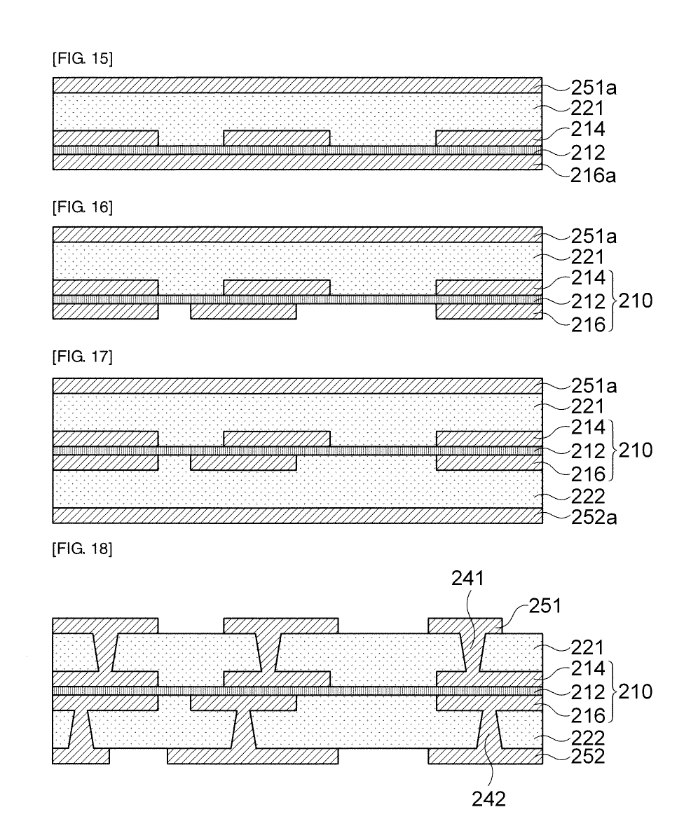

Then, as shown in FIG. 15, a first insulating material 221 and a first metal layer 251a configured to cover the first pattern electrode 214 are formed. Here, the first insulating material 221 may be formed of various materials having low electrical conductivity and through which little current can pass, such as prepreg, polyimide, polyethyeleneterepthalate (PET), cyanide ester, Ajinomoto build up film (ABF), epoxy, or the like.

In addition, the first metal layer 251a may be formed of a metal material such as copper (Cu), silver (Ag), gold (Au), aluminum (Al), iron (Fe), titanium (Ti), tin (Sn), nickel (Ni) or molybdenum (Mo).

Next, as shown in FIG. 16, the second electrode layer 216a is selectively removed to form a second pattern electrode 216.

Then, as shown in FIG. 17, a second insulating material 222 and a second metal layer 252a configured to cover the second pattern electrode 216 are sequentially deposited and formed, as shown in FIG. 18, first and second vias 241 and 242 which are inner layer vias through which the first and second insulating materials 221 and 222 are processed, are formed, and first and second circuit patterns 251 and 252, which are inner layer circuit patterns, are formed on upper and lower surfaces of the first and second insulating materials 221 and 222.

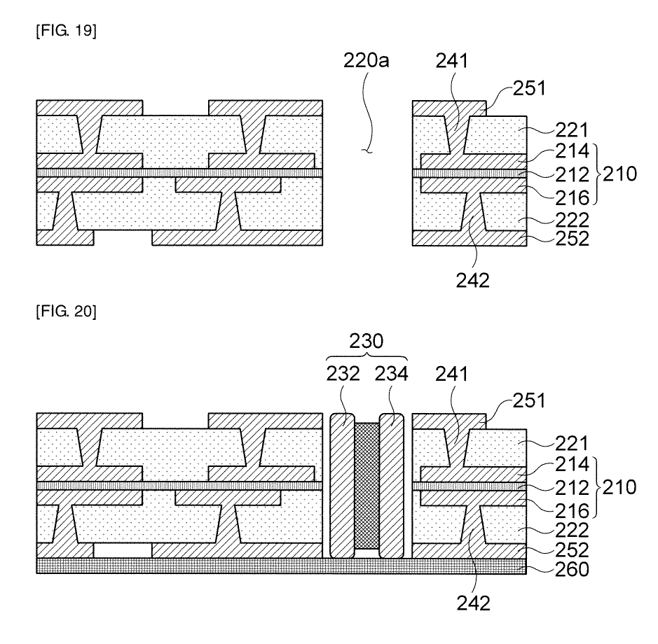

Next, as shown in FIG. 19, a cavity 220a is formed to pass through areas of the first and second insulating materials 221 and 222 in which the first and second pattern electrodes 214 and 216 are not formed. That is, in order to mount the chip capacitor 230, the cavity 220a is formed to pass through the region of the first and second insulating materials 221 and 222, in which the first and second pattern electrodes 214 and 216 are not formed, from one surface to the other surface.

Here, the cavity 220a may be formed in the first and second insulating materials 221 and 222 through laser cutting, routing, punching, or the like.

Next, as shown in FIG. 20, a fixing tape 260 is attached to a lower surface of the second insulating material 221 to cover the cavity 220a, and the chip capacitor 230 is inserted into the cavity 220a.

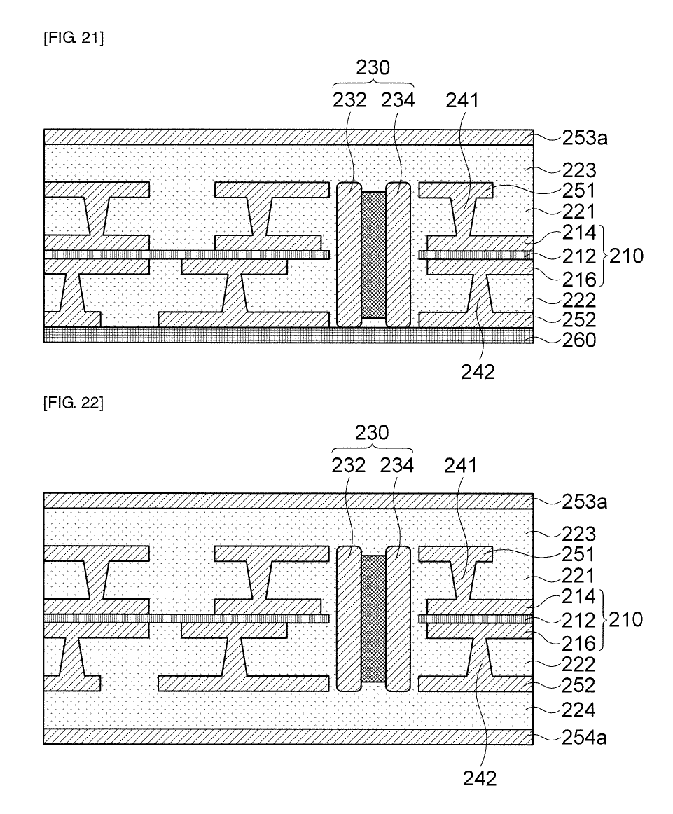

Next, as shown in FIG. 21, a third insulating material 223 and a third metal layer 253a, which are outer insulating materials configured to cover the first circuit pattern 251 and the chip capacitor 230 are applied, as shown in FIG. 22, the fixing tape 260 is removed, and a fourth insulating material 224 and a fourth metal layer 254a, which are outer insulating materials configured to cover the second circuit pattern 252 and the chip capacitor 230.

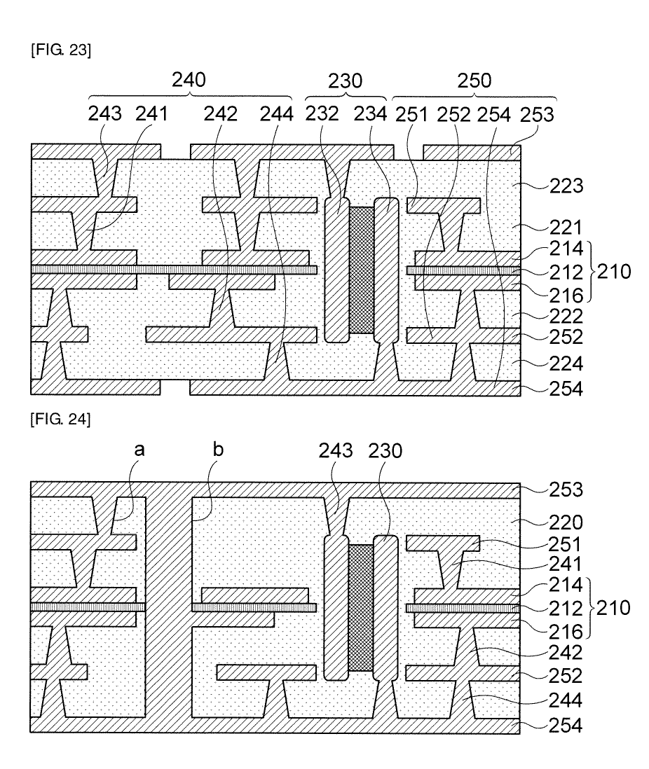

Next, as shown in FIG. 23, an outer layer via and an outer layer circuit pattern through which the outer insulating materials are processed are formed. More specifically describing, third and fourth vias 243 and 244 through which the third and fourth insulating materials 223 and 224 are processed are formed, and third and fourth circuit patterns 253 and 254 are formed at upper and lower surfaces of the third and fourth insulating materials 223 and 224.

A resist having an opening configured to expose portions of the third and fourth circuit patterns 253 and 254 is formed at the printed circuit board having an embedded capacitor, a process of forming a surface-treated layer (not shown) on the exposed third and fourth circuit patterns 253 and 254 may be formed, and an outer layer may be further formed according to a conventional buildup process.

Meanwhile, in the printed circuit board having an embedded capacitor in accordance with an exemplary embodiment of the present invention, as shown in FIG. 1, any one electrode of the first and second device electrodes of the chip capacitor may be electrically connected to the sheet-shaped capacitor through the via according to a thickness of the chip capacitor or a direction of the device electrode, and as shown in FIG. 3, both of the first and second device electrodes of the chip capacitor may be electrically connected to the sheet-shaped capacitor through the via.

FIG. 24 is a cross-sectional view showing a variant of the via shown in FIG. 23. Referring to FIG. 24, a structure of the via formed at the printed circuit board having an embedded capacitor may have a shape in which a blind via-hole (BVH) is continuously formed as shown in a, or in which a plated through-hole (PTH) is formed as shown in b. In this case, the inside of the blind via-hole and the plated through-hole may be plated with a metal material such as copper (Cu).

Meanwhile, an active device may be mounted on a position of the substrate in which the chip capacitor is mounted.

As can be seen from the foregoing, according to the printed circuit board having an embedded capacitor and the method of manufacturing the same in accordance with an exemplary embodiment of the present invention, as the sheet-shaped capacitor and the chip capacitor are implemented to be mounted in the same layer of the substrate, a current supply ability can be improved, and a low tolerance in capacity at a high capacity and a low capacity can be required, enabling application to various fields.

In the above structure, since a minimal thickness of the substrate can be maintained while two kinds of capacitors are mounted therein, reliability can be secured and a thin substrate having an embedded capacitor can be implemented.

In the operation and function, in comparison with a type in which only the chip capacitor is mounted, when both of the chip capacitor and the sheet-shaped capacitor are mounted, a current supply ability and efficiency can be improved. In addition, in the type in which only the chip capacitor is mounted, a decrease in impedance is difficult due to temperature dependency of a capacitance value or local concentration of the pattern. However, as the capacitors having different properties are mixed and used, a tolerance in capacitance value can be improved, and since the pattern is not locally concentrated, the impedance can be improved. Further, since insufficient stability of the current is supplemented, operational reliability at a radio frequency can be improved.

Such a substrate structure having high capacitance and low loss can be applied to a packaging substrate (4-6 Layers), and thus, a high performance thin complex substrate having an embedded capacitor including the printed circuit board having an embedded capacitor can be implemented.

Embodiments of the invention have been discussed above with reference to the accompanying drawings. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention.

What is claimed is:

1. A printed circuit board having an embedded capacitor comprising:
at least one sheet-shaped capacitor;
an insulating material configured to cover the sheet-shaped capacitor; and
a chip capacitor mounted in the insulating material to be parallelly disposed at one side of the sheet-shaped capacitor.

2. The printed circuit board having an embedded capacitor according to claim 1, wherein the chip capacitor is parallelly disposed at one side of the sheet-shaped capacitor in a horizontal direction.

3. The printed circuit board having an embedded capacitor according to claim 1, wherein the chip capacitor is connected to the sheet-shaped capacitor in series or in parallel.

4. The printed circuit board having an embedded capacitor according to claim 1, wherein the sheet-shaped capacitor comprises:
a dielectric body; and
first and second pattern electrodes formed at upper and lower surfaces of the dielectric body, respectively.

5. The printed circuit board having an embedded capacitor according to claim 4, wherein the dielectric body is formed of any one of an organic material, ceramic and a ceramic-filled organic material, or a combination thereof.

6. The printed circuit board having an embedded capacitor according to claim 4, wherein the first and second pattern electrodes are formed of a metal foil.

7. The printed circuit board having an embedded capacitor according to claim 1, further comprising:
a via formed by processing the insulating material to electrically connect the sheet-shaped capacitor and the chip capacitor; and
a circuit pattern formed inside or an outermost surface of the insulating material.

8. The printed circuit board having an embedded capacitor according to claim 7, wherein the chip capacitor comprises:
a first device electrode; and
a second device electrode formed at a position opposite to the first device electrode.

9. The printed circuit board having an embedded capacitor according to claim 8, wherein the chip capacitor is formed such that the first and second device electrodes are exposed to the insulating material, and
the first and second device electrodes are electrically connected to the sheet-shaped capacitor through a circuit pattern disposed at the outermost surface of the insulating material.

10. The printed circuit board having an embedded capacitor according to claim 8, wherein the chip capacitor is formed such that the first and second device electrodes are buried in the insulating material, and
the first and second device electrodes are electrically connected to the sheet-shaped capacitor through the via.

11. A method of manufacturing a printed circuit board having an embedded capacitor comprising:
forming at least one sheet-shaped capacitor and an insulating material configured to cover the sheet-shaped capacitor; and
mounting a chip capacitor in the insulating material to be parallelly disposed at one side of the sheet-shaped capacitor.

12. The method of manufacturing a printed circuit board having an embedded capacitor according to claim 11, wherein forming the at least one sheet-shaped capacitor and the insulating material configured to cover the sheet-shaped capacitor comprises:
providing a dielectric body;
forming a first pattern electrode on one surface of the dielectric body;
forming a first insulating material to cover the first pattern electrode; and
forming a second pattern electrode on the other surface of the dielectric body to oppose the first pattern electrode.

13. The method of manufacturing a printed circuit board having an embedded capacitor according to claim 12, wherein mounting the chip capacitor in the insulating material to be parallelly disposed at one side of the sheet-shaped capacitor comprises:
forming a cavity to pass through an area of the first insulating material in which the first and second pattern electrodes are not formed;
mounting the chip capacitor in the cavity; and
forming a second insulating material to cover the chip capacitor.

14. The method of manufacturing a printed circuit board having an embedded capacitor according to claim 13, after forming the cavity, further comprising attaching a fixing tape to one surface of the first insulating material to cover the cavity; and
after forming the second insulating material, further comprising removing the fixing tape.

15. The method of manufacturing a printed circuit board having an embedded capacitor according to claim 13, after forming the second insulating material, further comprising:
processing at least one insulating material of the first and second insulating materials and forming a via to electrically connect the sheet-shaped capacitor and the chip capacitor; and
forming a circuit pattern on at least one insulating material of the first and second insulating materials.

16. The method of manufacturing a printed circuit board having an embedded capacitor according to claim 11, wherein forming the insulating material to cover the at least one sheet-shaped capacitor and the sheet-shaped capacitor comprises:
providing a dielectric body;
forming a first pattern electrode on one surface of the dielectric body;
forming a first insulating material to cover the first pattern electrode;
forming a second pattern electrode on the other surface of the dielectric body to oppose the first pattern electrode; and
forming a second insulating material to cover the second pattern electrode.

17. The method of manufacturing a printed circuit board having an embedded capacitor according to claim 11, wherein mounting the chip capacitor in the insulating material to be parallelly disposed at one side of the sheet-shaped capacitor comprises:
forming a cavity to pass through areas of the first and second insulating materials in which the first and second pattern electrodes are not formed;
mounting the chip capacitor in the cavity; and
forming an outer insulating material to cover the chip capacitor.

18. The method of manufacturing a printed circuit board having an embedded capacitor according to claim 17, after forming the cavity, further comprising attaching a fixing tape to one surface of the first or second insulating material to cover the cavity, and
after forming the outer insulating material, further comprising removing the fixing tape.

19. The method of manufacturing a printed circuit board having an embedded capacitor according to claim 17, before forming the cavity, further comprising:
forming an inner layer via to process at least one insulating material of the first and second insulating materials; and
forming an inner layer circuit pattern on at least one insulating material of the first and second insulating materials.

20. The method of manufacturing a printed circuit board having an embedded capacitor according to claim 17, after forming the outer insulating material, further comprising:
forming an outer layer via to process the outer insulating material; and
forming an outer layer circuit pattern on the outer insulating material.
